(19) United States
(12) Patent Application Publication
(10) Pub. No.: US 2025/0109548 A1
(43) Pub. Date: Apr. 3, 2025

(54) NANO-COMPOSITE MATERIAL-BASED INTELLIGENT FIREPROOF TEXTILE AND PREPARATION METHOD THEREFOR

(71) Applicant: SOOCHOW UNIVERSITY, Suzhou (CN)

(72) Inventors: Min ZHENG, Suzhou (CN); Zuoshan WANG, Suzhou (CN); Wangyi ZHAI, Suzhou (CN)

(21) Appl. No.: 18/726,997

(22) PCT Filed: Feb. 24, 2023
(86) PCT No.: PCT/CN2023/078274

§ 371 Date: Jul. 5, 2024

(30) Foreign Application Priority Data
Jan. 7, 2022 (CN) 202210015485.6

(51) Int. Cl. D06M 11/48; D06M 11/74

(52) U.S. Cl. CPC D06M 11/48; D06M 11/74

(57) ABSTRACT

A nano-composite material-based intelligent fireproof textile and a preparation method therefor. Titanium aluminum carbide powder is added into a mixed solution of hydrochloric acid and lithium fluoride, and a reaction takes place under the condition that the temperature of a water bath is 40-50° C.; the reactants are washed to be neutral, centrifugation is performed, a precipitate is ultrasonically dispersed in deionized water, ammonium molybdate powder is added, irradiation under ultraviolet light is performed, and dialyzing and drying are performed, to obtain a molybdenum oxide quantum dot titanium carbide composite material, which is dispersed as a nano-slurry, and a rolling-baking-roasting process is used to finish a pretreated fabric, to obtain a nano-composite material-based intelligent fireproof textile. The molybdenum oxide quantum dot titanium carbide composite material is prepared on the basis of etching and ion intercalation principles, and it is combined with the fabric via post-finishing, so that the textile has fire early warning and smoke suppression functions, which is beneficial for the further application of functionalized nano-materials in the field of textiles.

### FIELD OF THE INVENTION

The present invention relates to an intelligent fireproof textile based on a nano-composite material and a preparation method therefor, and belongs to the technical field of functional textiles.

### BACKGROUND OF THE INVENTION

Cellulose fiber fabrics are a beloved textile that has flexibility, comfort, and biodegradability, so that the production is increasing. However, the inherent flammability of cellulose fiber fabrics brings a high risk of fire, posing a serious threat to people's lives and property safety. To improve its fire safety, many kinds of flame retardants containing halogen, phosphorus, or nitrogen have been developed. However, with the rapid development and widespread application of the Internet of Things (IoT), there is an urgent need for a more intelligent fire prevention method.

It is an effective way to reduce fire hazards to enable textile a fire pre-warning capability, that is, to prevent it before being ignited. Before the combustion of textiles with early warning capability, the fire alarm system can be triggered due to the rapid change of the resistance or voltage. MXene, as an emerging two-dimensional transition metal carbide, due to its excellent thermoelectric performance, provides a new idea for designing an intelligent fireproof textile. When there is a temperature difference between the two ends of the MXene loaded fabric, the internal charge carriers quickly move to the hotter region, forming a stable potential difference. In addition, the layered nanostructure of MXene makes it a physical barrier for combustible gases, and the derived titanium dioxide can act as a catalyst at high temperature to promote the formation of continuous and dense carbon in the condensed phase. Hermawan A, Zhang B, Taufik A, and others used this principle to study the detection of toluene using nano CuO/MXene (ACS Applied Nano Materials, 2020, 3 (5)). However, the thinner thickness and rich end-capping groups make MXene easily stacked during use, thereby reducing the conductivity and application performance of the material.

### SUMMARY OF THE INVENTION

In view of the deficiencies of the prior art, the present invention provides a nano-composite material-based intelligent fireproof textile with high temperature change detection sensitivity, fast response and excellent cycling stability and repeatability, and a preparation method thereof.

The technical solution for achieving the purpose of the present invention is to provide a preparation method of an intelligent fireproof textile based on a nano-composite material, characterizing in comprising the following steps:
(1) preparing a mixed solution of lithium fluoride and hydrochloric acid according to a mass percentage concentration of 7-10%, adding titanium aluminum carbide into the mixed solution at a mass concentration of 5-8%, reacting at a water bath temperature of 40-50° C. for 18-28 h, washing the obtained reactant to be neutral, centrifuging, and ultrasonically dispersing in deionized water;
(2) dissolving ammonium molybdate powder in the solution prepared in step (1) according to the mass percentage concentration of ammonium molybdate of 2-3%, reacting under ultraviolet irradiation, and then dialyzing and drying to obtain the molybdenum oxide quantum dot titanium carbide composite material;
(3) preparing the molybdenum oxide quantum dot titanium carbide composite material obtained in step (2) into a dispersion, and performing rolling-baking-roasting on the washed and dried fabric to obtain an intelligent fireproof textile.

In the above solution, in step (2), the reaction is performed for 20-40 min under the ultraviolet irradiation condition of 72 W. In step (3), the amount of the molybdenum oxide quantum dot titanium carbide composite material is 2-6 wt % relative to the weight of the fabric. In step (3), the rolling-baking-roasting process conditions are that the liquid rolling rate is 100-150%, the baking temperature is 80-110° C., and the roasting temperature is 120-140° C.

The technical solution of the present invention further includes an intelligent fireproof textile based on a nano-composite material obtained by the above preparation method.

The intelligent fireproof textile based on a nano-composite material of the present invention has a resistance temperature coefficient of-0.26%/° C.

The sensitivity of the temperature change detected by the textile is 0.5° C., and the response time of the detection temperature is 2.77 s.

That is, the temperature change of 0.5° C. can be detected by the textile provided by the present invention, and the detection and response can be completed in 2.77 s.

The present invention constructs a heterojunction through molybdenum oxide quantum dots at a nanoscale, and provides an effective way for solving the problems existing in the prior art. Although the molybdenum oxide quantum dots do not directly participate in the charge transport process, due to its excellent electron mobility, the electron transport speed between the MXene nanosheets can be increased, the stacking of the sheet layers can be improved, and meanwhile, the generation of smoke can be reduced. According to the above principle, in order to overcome the defects of the prior art in the aspects of fabric fireproof early warning, smoke suppression and the like, through electrostatic attraction, the two nano materials of the molybdenum oxide quantum dots and titanium carbide, with strong adsorbability, are self-assembled together to form a heterostructure. And then, the composite material is combined with the fabric, and the dual effects of smoke suppression and temperature response of the fabric are achieved at the same time.

Compared with the prior art, the present invention has the following beneficial effects:

According to the intelligent fireproof textile based on a nano-composite material provided by the present invention, the resistance temperature coefficient (i.e. sensitivity) of the finished fabric reaches-0.26%/° C., and at the same time, the temperature variation can be quickly responded within 2.77 s, and the temperature variation of 0.5° C. can be detected at the lowest, and has excellent cycling stability and repeatability; and when the actual fire condition is simulated, the fire alarm capability is still shown after five times of combustion, and the temperature response and smoke suppression function of the textile are achieved. The preparation method of the intelligent fireproof textile provided by the invention has the advantages of simplicity, rapidness, low equipment requirement and the like, and is beneficial to industrial production.

### BRIEF DESCRIPTION OF THE DRAWINGS

FIG. 1 is an SEM image of a finished cotton fabric prepared in Embodiment 1 of the present invention.

FIG. 2 is a comparison diagram of the density of the finished cotton fabric and the untreated cotton fabric prepared in Embodiment 1 of the present invention.

FIG. 3 is a sensitivity diagram of the finished cotton fabric prepared in Embodiment 1 of the present invention.

FIG. 4 is a response time and resolution diagram of the finished cotton fabric prepared in Embodiment 1 of the present invention.

FIG. 5 is a multi-cycle and stability diagram of the finished cotton fabric prepared in Embodiment 1 of the present invention.

FIG. 6 is an output voltage diagram of the finished cotton fabric prepared in Embodiment 1 of the present invention after combustion.

### DETAILED DESCRIPTION OF THE INVENTION

The technical solution of the present invention is further described below with reference to the accompanying drawings and specific embodiments.

### Embodiment 1

1.5 g of lithium fluoride was weighed and dissolved in 20 mL of hydrochloric acid (with a concentration of 9 M), 1 g of titanium aluminum carbide powder was slowly added, and the reaction was carried out for 24 h under a water bath with a temperature of 45° C.; washing the obtained reactant to neutral, centrifuging, and ultrasonically dispersing in 100 ml of deionized water; and adding 2 g of ammonium molybdate into the mixture, irradiating for 30 min under 72 W ultraviolet light, dialyzing, and freeze-drying to obtain the molybdenum oxide quantum dot titanium carbide composite material.

4 g/L of the cleaning solution is prepared, the cotton knitted fabric is pretreated for 30 min at a temperature of 80° C., and the cotton knitted fabric is dried for later use.

The prepared molybdenum oxide quantum dot titanium carbide composite material is dispersed into a nano slurry, the cotton knitted fabric is subjected to rolling-baking-roasting according to the amount of 2 wt %, the liquid rolling rate is 100%, the baking temperature is 90° C., and the roasting temperature is 120° C. to obtain a textile having a temperature response and a smoke suppression function.

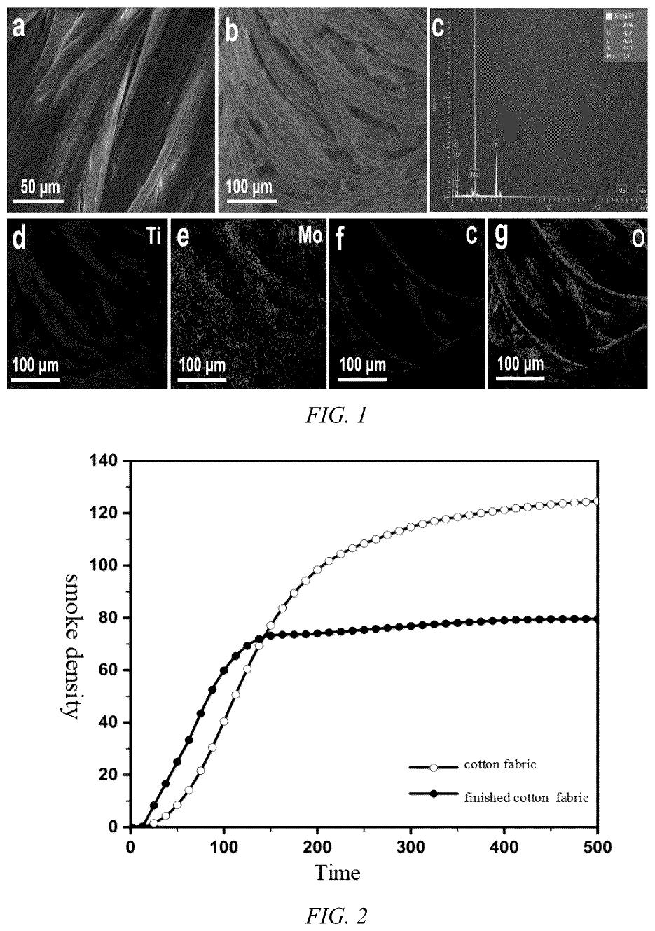

Referring to FIG. 1, a scanning electron microscope image of a finished cotton fabric prepared in this embodiment is shown. Wherein a is a scanning electron microscope image of unfinished cotton fabric, b is a scanning electron microscope image of finishing cotton fabric, c is an energy spectrum, d is a Ti distribution map, e is a Mo distribution map, f is a C distribution map, and g is an O distribution map. It can be seen from FIG. 1 that the surface of the cotton fiber is coated with a layer of uniform material, and part of the composite material enters the fiber pores and has good adhesion.

Referring to FIG. 2, FIG. 2 is a comparison diagram of the smoke density of the finished cotton fabric and the untreated cotton fabric prepared in this embodiment. It can be seen from FIG. 2 that the density of the smoke released from the finished cotton fabric is significantly reduced, and the peak value is only 79.5.

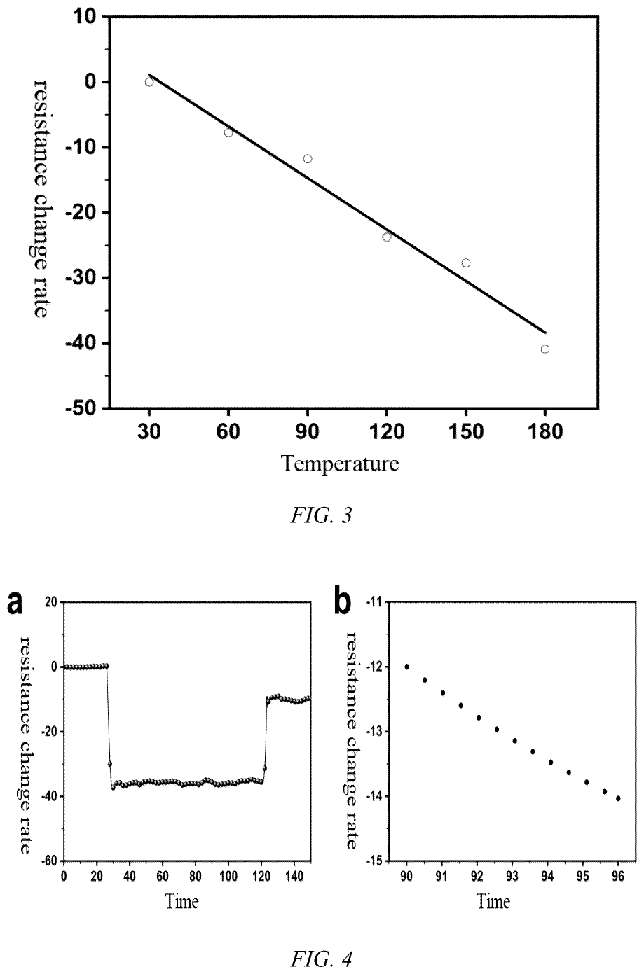

Referring to FIG. 3, FIG. 3 is a sensitivity image of the finished cotton fabric prepared in this embodiment. The sensitivity of finishing the cotton fabric is-0.26%/° C.

FIG. 4 is a response time and resolution diagram of the finished cotton fabric prepared in this embodiment, where a is the response time image of the finished cotton fabric prepared in this embodiment, the response time of finishing the cotton fabric is 2.77 s, the recovery time is 2.9 s. FIG. 4b is the resolution image of the finished cotton fabric prepared in this embodiment, and the minimum temperature change of the cotton fabric can be detected to 0.5° C.

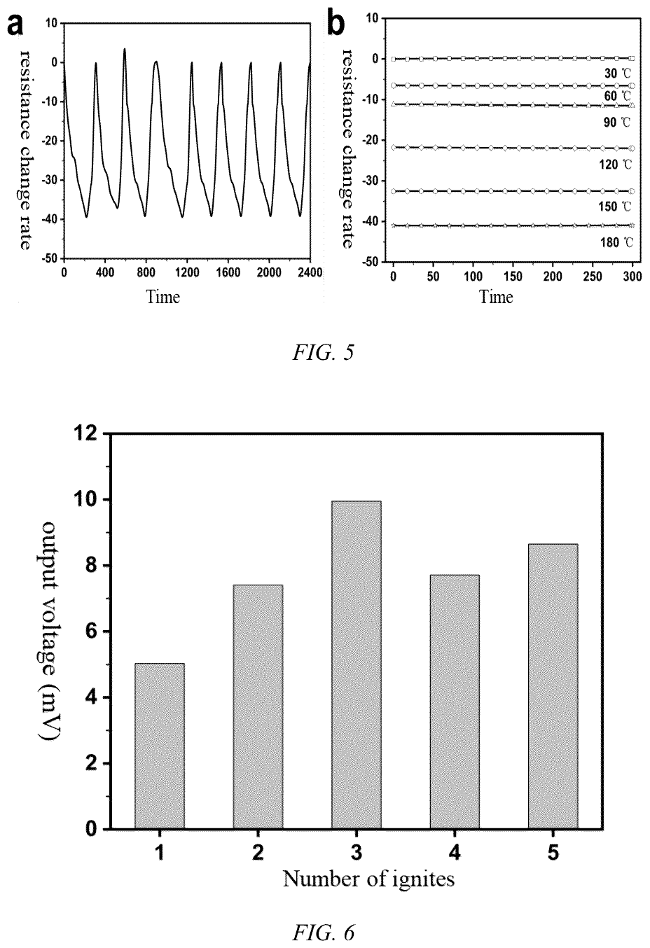

Referring to FIG. 5, FIG. 5 is a multi-cycle and stability diagram of the finished cotton fabric prepared in this embodiment. FIG. 5a is a number of cycle images of the finished cotton fabric prepared in this embodiment of the present disclosure, and after 8 cycles of finishing the cotton fabric, the resistance of the cotton fabric is not significantly changed. FIG. 5b is the stability image of the finished cotton fabric prepared in this embodiment, and after finishing the continuous test of the cotton fabric for 5 min, the resistance changes at different temperatures are almost negligible.

Referring to FIG. 6, FIG. 6 is an output voltage image of the finished cotton fabric prepared in this embodiment after different times of ignition. It can be found that after five times of ignition, the finished cotton fabric can still output an electrical signal.

### Embodiment 2

1.5 g of lithium fluoride was weighed and dissolved in 20 mL of hydrochloric acid (with a concentration of 9 M), 1.2 g of titanium aluminum carbide powder was slowly added, and the reaction was carried out for 24 h under a water bath with a temperature of 50° C.; washing the obtained reactant to neutral, centrifuging, and ultrasonically dispersing in 100 ml of deionized water; and adding 2.5 g of ammonium molybdate into the mixture, irradiating for 40 min under 72 W ultraviolet light, dialyzing, and freeze-drying to obtain the molybdenum oxide quantum dot titanium carbide composite material.

5 g/L of the cleaning solution is prepared, the viscose knitted fabric is pretreated for 30 min at a temperature of 100° C., and the viscose knitted fabric is dried for later use.

The prepared molybdenum oxide quantum dot titanium carbide composite material is dispersed into nano slurry, the viscose knitted fabric is subjected to rolling-baking-roasting according to the amount of 4 wt %, the liquid rolling rate is 110%, the baking temperature is 90° C., and the roasting temperature is 130° C. to obtain a textile having a temperature response and a smoke suppression function.

### Embodiment 3

1.5 g of lithium fluoride was weighed and dissolved in 20 mL of hydrochloric acid (with a concentration of 9 M), 1 g of aluminum titanium carbide powder was slowly added, and the reaction was carried out for 24 h under a water bath with a temperature of 50° C.; washing the obtained reactant to neutral, centrifuging, and ultrasonically dispersing in 100 ml of deionized water; and adding 2.0 g of ammonium molybdate powder, wherein the mixture is irradiated under ultraviolet light of 72 W for 30 min, and dialyzed and freeze-dried to obtain the molybdenum oxide quantum dot titanium carbide composite material.

4 g/L of the cleaning solution is prepared, the cotton shuttle fabric is pretreated for 30 min at a temperature of 80° C., and the cotton shuttle fabric is dried for later use.

The prepared molybdenum oxide quantum dot titanium carbide composite material is dispersed into nano slurry, the cotton shuttle fabric is subjected to rolling-baking-roasting according to the amount of 6 wt %, the liquid rolling rate is 100%, the baking temperature is 90° C., and the roasting temperature is 130° C. to obtain a textile having a temperature response and a smoke suppression function.

### Embodiment 4

1.5 g of lithium fluoride was weighed and dissolved in 20 mL of hydrochloric acid (with a concentration of 9 M), 1.2 g of aluminum titanium carbide powder was slowly added, and the reaction was carried out for 24 h under a water bath with a temperature of 50° C.; washing the obtained reactant to neutral, centrifuging, and ultrasonically dispersing in 100 ml of deionized water; and adding 2.5 g of ammonium molybdate into the mixture, irradiating for 40 min under 72 W ultraviolet light, dialyzing, and freeze-drying to obtain the molybdenum oxide quantum dot titanium carbide composite material.

5 g/L of the cleaning solution is prepared, the viscose shuttle fabric is pretreated for 30 min at a temperature of 100° C., and the fabric is dried for later use.

The prepared molybdenum oxide quantum dot titanium carbide composite material is dispersed into nano slurry, the viscose shuttle fabric is subjected to rolling-baking-roasting according to the amount of 4 wt %, the liquid rolling rate is 110%, the baking temperature is 90° C., and the roasting temperature is 130° C. to obtain a textile having a temperature response and a smoke suppression function.

What we claim is:

1. A preparation method of an intelligent fireproof textile based on a nano-composite material, characterizing in comprising the following steps:
(1) preparing a mixed solution of lithium fluoride and hydrochloric acid according to a mass percentage concentration of 7-10%, adding titanium aluminum carbide into the mixed solution at a mass concentration of 5-8%, reacting at a water bath temperature of 40-50° C. for 18-28 h, washing the obtained reactant to be neutral, centrifuging, and ultrasonically dispersing in deionized water;
(2) dissolving ammonium molybdate powder in the solution prepared in step (1) according to the mass percentage concentration of ammonium molybdate of 2-3%, reacting under ultraviolet irradiation, and then dialyzing and drying to obtain the molybdenum oxide quantum dot titanium carbide composite material;
(3) preparing the molybdenum oxide quantum dot titanium carbide composite material obtained in step (2) into a dispersion, and performing rolling-baking-roasting on the washed and dried fabric to obtain an intelligent fireproof textile.

2. The preparation method of the intelligent fireproof textile based on a nano-composite material according to claim 1, wherein in step (2), the reaction is performed for 20-40 min under the ultraviolet irradiation condition of 72 W.

3. The preparation method of the intelligent fireproof textile based on a nano-composite material according to claim 1, wherein in step (3), the amount of the molybdenum oxide quantum dot titanium carbide composite material is 2-6 wt % relative to the weight of the fabric.

4. The preparation method of the intelligent fireproof textile based on a nano-composite material according to claim 1, wherein in step (3), the rolling-baking-roasting process conditions are that the liquid rolling rate is 100-150%, the baking temperature is 80-110° C., and the roasting temperature is 120-140° C.

5. An intelligent fireproof textile based on a nano-composite material obtained by the preparation method of claim 1.

6. The intelligent fireproof textile based on a nano-composite material according to claim 5, wherein the resistance temperature coefficient of the textile is-0.26%/° C.

7. The intelligent fireproof textile based on a nano-composite material according to claim 5, wherein the sensitivity of the temperature change detected by the textile is 0.5° C., and the response time of the detection temperature is 2.77 s.
